(19) United States
(12) Patent Application Publication
(10) Pub. No.: US 2018/0308937 A1
(43) Pub. Date: Oct. 25, 2018

(54) SILICON CARBIDE SEMICONDUCTOR DEVICE AND METHOD OF MANUFACTURING SILICON CARBIDE SEMICONDUCTOR DEVICE

(71) Applicant: Fuji Electric Co., Ltd., Kanagawa (JP)

(72) Inventors: Takayuki HIROSE, Kanagawa (JP); Yutaka TERAO, Nagano (JP); Aki TAKIGAWA, Tokyo (JP); Hideaki TERANISHI, Tokyo (JP); Akira SAITO, Kanagawa (JP)

(73) Assignee: Fuji Electric Co., Ltd., Kanagawa (JP)

(21) Appl. No.: 15/915,979

(22) Filed: Mar. 8, 2018

(30) Foreign Application Priority Data
Apr. 24, 2017 (JP) 2017-085727

(51) Int. Cl. H01L 29/16; H01L 29/51; H01L 29/78

(52) U.S. Cl. CPC H01L 29/1608; H01L 29/78; H01L 29/518

(57) ABSTRACT

Provided is a MOS gate using a thermally oxidized film as a gate insulating film on the front surface of a silicon carbide substrate. A ratio of an excess carbon amount at an SiO₂/SiC interface in relation to a carbon amount in the silicon carbide substrate is 0.1 or less. The excess carbon at the SiO₂/SiC interface is generated during thermal oxidation for forming the gate insulating film. The excess carbon is a compound constituted of carbon atoms having the pi (it) bonds, and specifically is graphite, for example. The amount of nitrogen at the SiO₂/SiC interface is 1.4×10¹⁵/cm² to 1.8×10¹⁵/cm², inclusive, for example.

### BACKGROUND OF THE INVENTION

### Technical Field

The present invention relates to a silicon carbide semiconductor device and to a method of manufacturing a silicon carbide semiconductor device.

### Background Art

Silicon carbide (SiC) has advantages over silicon (Si) such as having a higher dielectric breakdown field strength and having a higher heat conductivity, and thus in particular, applications in power devices are expected. Similar to silicon, silicon carbide can form an oxide film (SiO₂ film) by thermal oxidation. Thus, among semiconductor devices using silicon carbide (hereinafter referred to as a “silicon carbide semiconductor devices”), MOS-type silicon carbide semiconductor devices including a MOS gate (insulated gate having a metal-oxide film-semiconductor structure) in which the oxide film formed by thermal oxidation is used as the gate insulating film are being developed.

A method that aims to improve and stabilize characteristics by forming on a semiconductor substrate made of silicon carbide (hereinafter referred to as “silicon carbide substrate”) an oxide film as the gate insulating film by performing thermal oxidation in an oxynitride atmosphere including nitrogen monoxide (NO) and nitrous oxide (N₂O) is publicly known, for example. By forming the gate insulating film by thermal oxidation, channel mobility is improved and shift ΔVth in a gate threshold voltage Vth by the bias temperature stress test (BT test) is mitigated.

As a MOS-type silicon carbide semiconductor device with improved channel mobility, a device has been proposed that includes a gate insulating film that is in contact with the silicon carbide semiconductor layer, and that includes a first film containing nitrogen and a second film provided between the first film and the gate electrode (see Patent Document 1 (paragraphs [0042], [0045]; FIG. 2) below, for example). In Patent Document 1 below, by forming the first and second films by deposition, a gate insulating film that has a prescribed nitrogen concentration distribution and that contains almost no carbon is formed, and the channel mobility is increased.

### RELATED ART DOCUMENT

### Patent Document

Patent Document 1: Japanese Patent Application Laid-Open Publication No. 2014-222735

### SUMMARY OF THE INVENTION

However, in conventional silicon carbide semiconductor devices, forming a gate insulating film by thermal oxidation on the surface of a silicon carbide substrate (semiconductor chip) would result in excess carbon being generated at the junction interface between the gate insulating film and the silicon carbide substrate (hereinafter referred to as the SiO₂/SiC interface). As a result, the interface state (electron trap) density (Dit) at the SiO₂/SiC interface becomes high, which results in problems such as a decrease in channel mobility and shift ΔVth in the gate threshold voltage Vth.

Accordingly, the present invention is directed to a scheme that substantially obviates one or more of the problems due to limitations and disadvantages of the related art.

An object of the present invention is to provide a silicon carbide semiconductor device by which it is possible to reduce the occurrence of excess carbon at the SiO₂/SiC interface in order to solve problems caused by the above-mentioned conventional technique, and a method of manufacturing such a silicon carbide semiconductor device.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

In order to solve the above-mentioned problem and achieve the object of the present invention, as embodied and broadly described, in one aspect, the present disclosure provides a silicon carbide semiconductor device, including: a semiconductor substrate made of silicon carbide; a gate insulating film in contact with the semiconductor substrate on one main surface of the semiconductor substrate; and a gate electrode that is provided along the gate insulating film, and that opposes the semiconductor substrate with the gate insulating film sandwiched therebetween, wherein the gate insulating film is a thermally oxidized film, wherein nitrogen and excess carbon made of carbon atoms having the pi (π) bonds are present at an interface between the gate insulating film and the semiconductor substrate, wherein a ratio of an amount of the excess carbon at the interface between the gate insulating film and the semiconductor substrate, to an amount of carbon in a bulk of the semiconductor substrate is 0.1 or less, wherein the amount of the excess carbon at the interface between the gate insulating film and the semiconductor substrate is determined by an integral of area intensities of energy loss intensity distributions due to carbon atoms having the pi (π) bonds in the excess carbon obtained by Electron Energy Loss Spectroscopy, and wherein the amount of the carbon in the bulk of the semiconductor substrate is determined by an area intensity of an energy loss intensity distribution due to carbon atoms having the sigma (σ) bonds of the bulk of the semiconductor substrate obtained by the Electron Energy Loss Spectroscopy.

Also, in the above-mentioned silicon carbide semiconductor device, an amount of the nitrogen at the interface between the gate insulating film and the semiconductor substrate may be 1.4×10¹⁵/cm² to 1.8×10¹⁵/cm², inclusive.

Also, in another aspect, the present disclosure provides a silicon carbide semiconductor device, including: a semiconductor substrate made of silicon carbide; a gate insulating film in contact with the semiconductor substrate on one main surface of the semiconductor substrate; and a gate electrode that is provided along the gate insulating film, and that opposes the semiconductor substrate with the gate insulating film sandwiched therebetween, wherein the gate insulating film is a thermally oxidized film, wherein nitrogen and excess carbon made of carbon atoms having the pi (π) bonds are present at an interface between the gate insulating film and the semiconductor substrate, and wherein an amount of the nitrogen at the interface between the gate insulating film and the semiconductor substrate is 1.4×10¹⁵/cm² to 1.8×10¹⁵/cm², inclusive.

Also, in another aspect, the present disclosure provides a method of manufacturing a silicon carbide semiconductor device, including: preparing a semiconductor substrate made of silicon carbide; forming a gate insulating film on the semiconductor substrate, including thermally oxidizing a surface of the semiconductor substrate; and forming a gate electrode on the gate insulating film, wherein the gate insulating film is formed such that an amount of nitrogen accumulated at an interface between the gate insulating film and the semiconductor substrate is 1.4×10¹⁵/cm² to 1.8×10¹⁵/cm², inclusive.

Also, in the above-mentioned method of manufacturing a silicon carbide semiconductor device, the gate insulating film may be formed such that a ratio of an amount of excess carbon made of carbon atoms having the pi (π) bonds accumulated at the interface between the gate insulating film and the semiconductor substrate, to an amount of carbon in a bulk of the semiconductor substrate is set to 0.1 or less; the amount of the excess carbon at the interface between the gate insulating film and the semiconductor substrate may be determined by an integral of area intensities of energy loss intensity distributions due to carbon atoms having the pi (π) bonds in the excess carbon obtained by Electron Energy Loss Spectroscopy; and the amount of the carbon in the bulk of the semiconductor substrate may be determined by an area intensity of an energy loss intensity distribution due to carbon atoms having the sigma (σ) bonds in the silicon carbide of the bulk of the semiconductor substrate obtained by the Electron Energy Loss Spectroscopy.

Also, in the above-mentioned method of manufacturing a silicon carbide semiconductor device, the formation of the gate insulating film may include thermally oxidizing the semiconductor substrate in an oxynitride atmosphere including nitrogen monoxide or nitrous oxide.

Also, in the above-mentioned method of manufacturing a silicon carbide semiconductor device, the formation of the gate insulating film may include performing dry oxidation of the semiconductor substrate using dry oxygen as an oxidant, and subsequently thermally oxidizing the semiconductor substrate in an oxynitride atmosphere including nitrogen monoxide or nitrous oxide.

Also, in the above-mentioned method of manufacturing a silicon carbide semiconductor device, the formation of the gate insulating film may include performing wet oxidation of the semiconductor substrate using water vapor as an oxidant, and subsequently thermally oxidizing the semiconductor substrate in an oxynitride atmosphere including nitrogen monoxide or nitrous oxide.

Also, in the above-mentioned method of manufacturing a silicon carbide semiconductor device, the thermal oxidation of the semiconductor substrate may be performed at a temperature of 1200° C. to 1500° C., inclusive.

According to the silicon carbide semiconductor device and the method of manufacturing a silicon carbide semiconductor device according to the present invention, the effect of being able to reduce the occurrence of excess carbon at the SiO₂/SiC interface is achieved.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view showing a structure of a silicon carbide semiconductor device according to Embodiment 1.

FIG. 2 is a flowchart that schematically shows a method of manufacturing the silicon carbide semiconductor device according to Embodiment 1.

FIG. 3 is an energy loss intensity distribution chart showing an energy loss intensity distribution measured by EELS and spectra separated from the energy loss intensity distribution.

FIG. 4A is a descriptive view that schematically shows measurement points for EELS.

FIG. 4B is an energy loss intensity distribution chart showing an energy loss intensity distribution at each measurement point in FIG. 4A and spectra of excess carbon separated from the energy loss intensity distribution.

FIG. 4C is a characteristic view showing an area intensity distribution of a component spectrum of excess carbon at each measurement point of FIG. 4B.

FIG. 5 is a characteristic figure showing the relationship between the amount of nitrogen at the SiO₂/SiC interface and the gate threshold voltage shift ΔVth.

FIG. 6 is a characteristic figure showing the amount of nitrogen at the SiO₂/SiC interface and the excess carbon ratio at the SiO₂/SiC interface.

### DETAILED DESCRIPTION OF EMBODIMENTS

Below, embodiments of a silicon carbide semiconductor device and a method of manufacturing a silicon carbide semiconductor device according to the present invention will be described with reference to the attached drawings. In the description and attached drawings of the embodiment below, the same reference characters are assigned to similar configurations, and redundant descriptions thereof are omitted. Also, in the present specification, in notation of the Miller index, the “−” symbol is associated with the immediately following index, and placing the “−” before the index indicates that the index is negative.

### Embodiment 1

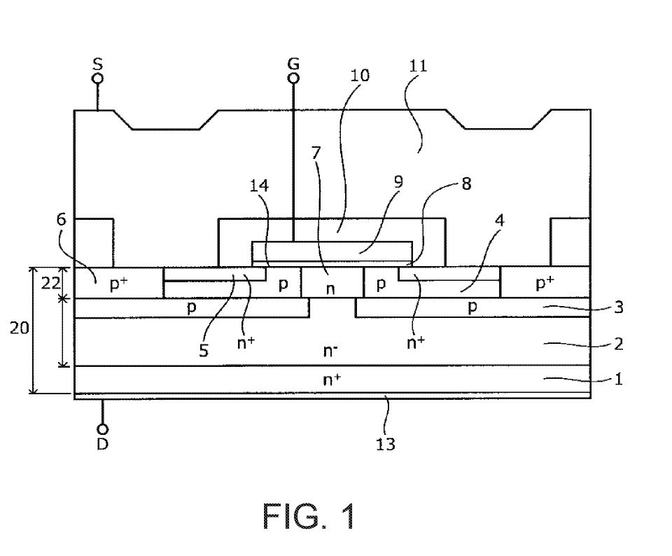

Regarding the structure of a silicon carbide (SiC) semiconductor device according to Embodiment 1, the example of a vertical MOSFET (metal oxide semiconductor field effect transistor) with a planar gate structure will be described. FIG. 1 is a cross-sectional view showing a structure of a silicon carbide semiconductor device according to Embodiment 1. FIG. 1 shows one unit cell (component unit of device) of a MOSFET, and other unit cells adjacent to the unit cell are omitted from the drawing. Also, FIG. 1 shows only the active region, and the edge termination region surrounding the periphery of the active region is omitted from the drawing.

The active region is a region through which current flows when the silicon carbide semiconductor device is in an ON state. The edge termination region is a region that is located between the active region and the side face of the silicon carbide substrate 20 (semiconductor substrate made of silicon carbide; semiconductor chip), and that maintains a breakdown voltage by reducing the electric field on the front surface-side (front surface of silicon carbide substrate 20) of an n⁻-type drift region 2. The edge termination region is provided with a p-type region constituting a guard ring or junction termination extension (JTE) structure, or a breakdown voltage structure such as a field plate or RESURF. The breakdown voltage is the maximum voltage at which a semiconductor device does not undergo a malfunction or receive damage.

The silicon carbide semiconductor device according to Embodiment 1 shown in FIG. 1 includes a MOS gate (insulated gate including metal-oxide film-semiconductor structure) on the front surface (front surface on the side of p-type silicon carbide layer 22) of the semiconductor substrate 20 (silicon carbide substrate) made of silicon carbide. The silicon carbide substrate 20 is a silicon carbide epitaxial substrate made by epitaxial growth of silicon carbide layers 21 and 22 to be an n⁻-type drift region 2 and a p-type base regions 4, on an n⁺-type starting substrate 1 made of silicon carbide. The MOS FET is constituted of p-type base regions 3 and 4, n⁺-type source regions 5, p⁺-type contact regions 6, an n-type JFET (junction FET) region 7, a gate insulating film 8, and a gate electrode 9.

The p-type base regions 3 are selectively provided on the surface layer of the source side (source electrode 11 side) of the n⁻-type silicon carbide layer 21. The portion of the n⁻-type silicon carbide layer 21 other than the p-type base regions 3 is the n⁻-type drift region 2. The p-type silicon carbide layer 22 is provided over the entire active region on the source-side surface of the n⁻-type silicon carbide layer 21 so as to cover the p-type base regions 3. The n⁺-type source regions 5, the p⁺-type contact regions 6, and the n-type JFET region 7 are selectively provided on the surface layer of the source side of the p-type silicon carbide layer 22. The n⁺-type source regions 5 and the p⁺-type contact regions 6 are in contact with each other.

The n⁺-type source regions 5 and the p⁺-type contact regions 6 oppose the p-type base regions 3 in the depth direction (vertical direction). The depth direction is the direction from the front surface to the rear surface of the silicon carbide substrate 20. The n-type JFET region 7 is disposed apart from the n⁺-type source regions 5 on the opposite side of the p⁺-type contact regions 6 in relation to the n⁺-type source regions 5. The n-type JFET region 7 is formed by converting (inverting) a portion of the p-type silicon carbide layer 22 to the n-type by ion implantation, and passes through the p-type silicon carbide layer 22 in the depth direction to reach the n⁻-type drift region 2. The n-type JFET region 7 functions as a drift region together with n⁻-type drift region 2.

The portion of the p-type silicon carbide layer 22 other than the n⁺-type source regions 5, the p⁺-type contact regions 6, and the n-type JFET region 7 is the p-type base regions 4. The p-type base regions 4 are in contact with the p-type base regions 3. The impurity concentration of the p-type base regions 4 may be lower than the impurity concentration of the p-type base regions 3. The p-type base regions 3 and the p-type base regions 4 function as the base region. On the surfaces of the portion of the p-type base regions 4 sandwiched between the n⁺-type source regions 5 and the n-type JFET region 7, the gate insulating film 8 is provided across the n⁺-type source regions 5 and the n-type JFET region 7. The gate insulating film 8 is a thermally oxidized film formed by thermally oxidizing the front surface of the silicon carbide substrate 20.

Specifically, the gate insulating film 8 is a thermally oxidized film formed by thermal oxidation. By performing thermal oxidation to form the gate insulating film 8, nitrogen (N) is accumulated at the junction interface 14 (SiO₂/SiC interface) between the gate insulating film 8 and the silicon carbide substrate 20. Also, as a result of thermal oxidation, excess carbon is generated at the SiO₂/SiC interface 14. By thermal oxidation to form the gate insulating film 8, the SiO₂/SiC interface 14 has formed thereon a layer that is a mixture of the thermally oxidized film and silicon carbide with a thickness of approximately 1 nm, for example, and this layer includes excess carbon and nitrogen.

The amount of nitrogen at the SiO₂/SiC interface 14 can be controlled by adjusting the temperature, partial pressure, and processing time for thermal oxidation to form the gate insulating film 8. As described below in detail, by setting the amount of nitrogen at the SiO₂/SiC interface 14 to 1.4×10¹⁵/cm² to 1.8×10¹⁵/cm², inclusive, the generation of excess carbon at the SiO₂/SiC interface 14 is reduced. As further explained below, in terms of the ratio of the excess carbon amount C2 at the SiO₂/SiC interface 14 in relation to the carbon amount C1 in the portion of the silicon carbide substrate 20 away from the SiO₂/SiC interface 14, this condition for the nitrogen amount means that the excess carbon ration satisfies at least a condition of being 0.1 or less (C2/C1≤0.1). Below, the ratio (C2/C1) of the excess carbon amount C2 of the SiO₂/SiC interface 14 in relation to the carbon amount C1 of the silicon carbide substrate 20 is referred to as an excess carbon ratio of the SiO₂/SiC interface 14. The method for calculating the excess carbon amount, the carbon amount, and the excess carbon ratio of the SiO₂/SiC interface 14 will be described later.

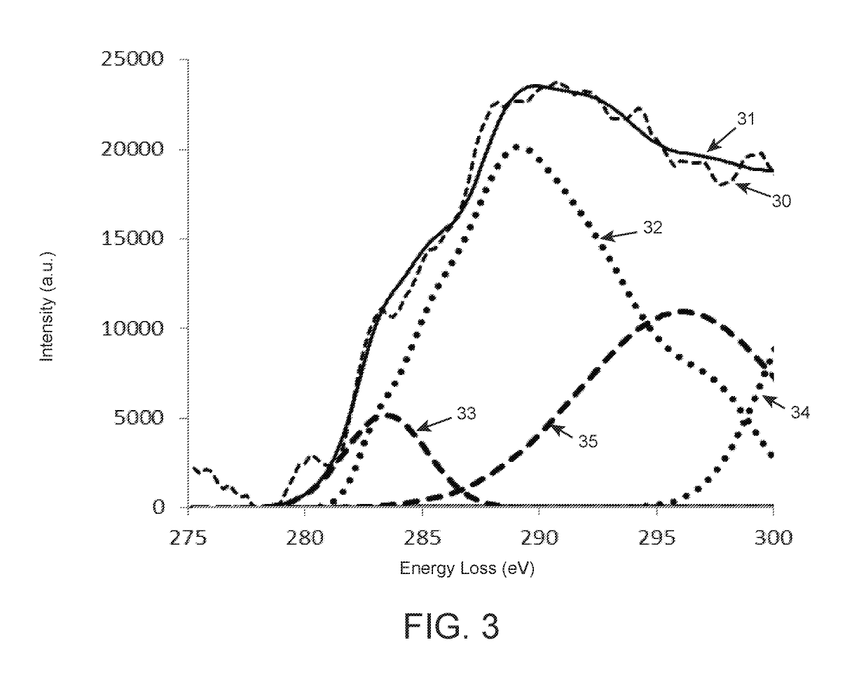

The silicon carbide of the SiO₂/SiC interface 14 is the silicon carbide constituting the silicon carbide substrate 20, and is a compound in which silicon and carbon are covalent bonded at a ratio of 1 to 1. Excess carbon is a compound constituted only of carbon atoms having an sp² hybrid orbital or sp hybrid orbital forming π bonds between adjacent carbon atoms, and specifically is graphite, for example. In EELS (Electron Energy Loss Spectroscopy), the spectrum of π bonds due to excess carbon appears at an energy loss range (approximately between 280 eV to 285 eV, for example) which is less than the energy loss values where the energy loss intensity distribution of the silicon carbide constituting the silicon carbide substrate 20 is at the maximum intensity (maximum value) (see FIG. 3). The maximum intensity of the energy loss intensity distribution of the excess carbon is lower than the maximum intensity of the energy loss intensity distribution of the silicon carbide constituting the silicon carbide substrate 20.

In order to quantitatively evaluate the amount of the excess carbon, the respective area intensities of the energy loss of the excess carbon and silicon carbide are obtained from the respective spectra of the excess carbons and the silicon carbide that are mutually separated from the energy loss intensity distribution obtained in the vicinity of the SiO₂/SiC interface 14 measured by the electron energy loss spectroscopy (EELS). EELS is a method of measuring energy lost by mutual interaction between an electron and an atom when the electron passes through. From the energy loss intensity distribution measured by EELS, it is possible to acquire separable spectra due to various bonds (e.g., single or double bond) between atoms and/or elements.

The gate electrode 9 is provided on the gate insulating film 8. The interlayer insulating film 10 is provided over the entire front surface of the substrate from the active region to the edge termination region, and covers the gate electrode 9. The source electrode 11 is in contact with the n⁺-type source regions 5 and the p⁺-type contact regions 6, and is electrically connected to the n⁺-type source regions 5 and the p⁺-type contact regions 6. Also, the source electrode 11 is electrically insulated from the gate electrode 9 by the interlayer insulating film 10. A drain electrode 13 is provided on the entire rear surface of the silicon carbide substrate 20 (rear surface of the n⁺-type starting substrate 1).

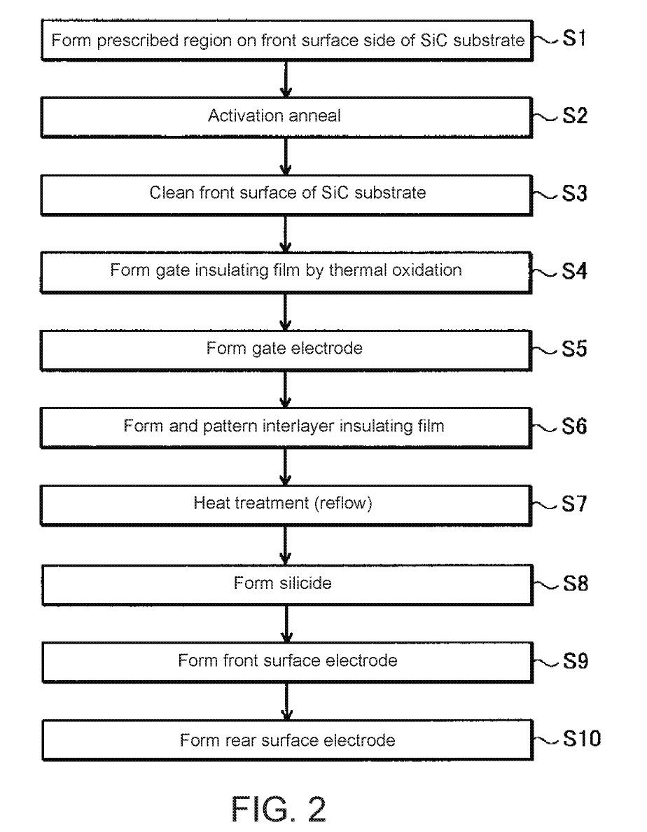

Next, a method of manufacturing a silicon carbide semiconductor device will be described. FIG. 2 is a flowchart that schematically shows a method of manufacturing the silicon carbide semiconductor device according to Embodiment 1. First, the n⁺-type starting substrate 1 (starting wafer) to be an n⁺-type drain region is prepared. Next, the n⁻-type silicon carbide layer 21 doped with an n-type impurity is epitaxially grown on the front surface of the n⁺-type starting substrate 1. Then, the p-type base regions 3 are selectively formed on the surface layer of the n⁻-type silicon carbide layer 21 by ion implantation of a p-type impurity. The portion of the n⁻-type silicon carbide layer 21 other than the p-type base regions 3 becomes the n⁻-type drift region 2.

Next, the p-type silicon carbide layer 22 doped with the p-type impurity is epitaxially grown on the surface of the n⁻-type silicon carbide layer 21. In the steps up to now, the silicon carbide substrate 20 (semiconductor wafer) in which the n⁻-type silicon carbide layer 21 and the p-type silicon carbide layer 22 were layered in that order on the front surface of the n⁺-type starting substrate 1 has been manufactured. Next, the p-type silicon carbide layer 22 is removed over the entire edge termination region (not shown) by etching. At this time, some of the surface layer of the n⁻-type silicon carbide layer 21 may be removed along with the p-type silicon carbide layer 22. As a result, the n⁻-type silicon carbide layer 21 is exposed on the front surface of the substrate at the edge termination region.

Next, a prescribed region constituting the MOS gate is formed on the front surface side of the silicon carbide substrate 20 (surface on the side of the p-type silicon carbide layer 22) (step S1). Specifically, ion implantation is repeatedly performed under differing conditions to selectively form the n⁺-type source regions 5, the p⁺-type contact regions 6, the n-type JFET region 7, and a p-type region constituting a breakdown voltage structure. The p-type region constituting the breakdown voltage structure is a p-type region constituting a guard ring or JTE structure, for example. The portion of the p-type silicon carbide layer 22 other than the n⁺-type source regions 5, the p⁺-type contact regions 6, and the n-type JFET region 7 becomes the p-type base regions 4.

Next, heat treatment (activation annealing) for activating entire regions that are formed by ion implantation is performed (step S2). Then, the front surface of the silicon carbide substrate 20 is cleaned with hydrogen fluoride (HF), for example (step S3). Then, the front surface of the silicon carbide substrate 20 is subjected to thermal oxidation under atmospheric pressure to form the gate insulating film 8 (step S4). The thermal oxidation of step 4 may be performed by dry oxidation using dry oxygen (O₂) as the oxidant, or by wet oxidation using water vapor (H₂O) as the oxidant. After forming the gate insulating film 8 by thermal oxidation, further thermal oxidation is performed under an oxynitride atmosphere including nitrogen monoxide (NO) or nitrous oxide (N₂O). This oxynitride atmosphere includes argon (Ar) gas and nitrogen (N₂) gas as a carrier gas, for example.

In step S4, in order to form the gate insulating film 8 by thermal oxidation, nitrogen is accumulated at the junction interface (SiO₂/SiC interface 14) between the gate insulating film 8 and the silicon carbide substrate 20. By controlling various conditions such as the temperature for thermal oxidation, partial pressure, and processing time for thermal oxidation, the amount of nitrogen at the SiO₂/SiC interface 14 is set to within the above-mentioned range. The process of step S4 may be performed by measuring the amount of nitrogen at the SiO₂/SiC interface 14 in a test piece 40 of silicon carbide that has undergone thermal oxidation to acquire in advance thermal oxidation conditions that would produce the amount of nitrogen at the SiO₂/SiC interface 14 that is within the above-mentioned range, for example. Specifically, it is preferable that the thermal oxidation temperature in step S4 be 1200° C. to 1500° C., inclusive, and the higher the temperature is, the shorter the time required is for the amount of nitrogen at the SiO₂/SiC interface 14 to be within the range. In the thermal oxidation of step S4, nitrogen similarly remains at the SiO₂/SiC interface 14 regardless of any of the above-mentioned methods. Alternatively, in step S4, a deposited oxide film may be first formed, and then thermal oxidation may be performed in an oxynitride atmosphere including nitrogen monoxide (NO) or nitrous oxide (N₂O) so that the surface of the silicon carbide substrate in contact with the deposited oxide film is subjected to thermal oxidation.

Next, polysilicon (poly-Si) is deposited on the gate insulating film 8 and patterned, thereby leaving polysilicon for the portion to be the gate electrode 9 (step S5). Then, the interlayer insulating film 10 is formed on the entire front surface of the silicon carbide substrate 20 so as to cover the gate electrode 9. Then, a contact hole is formed by patterning the interlayer insulating film 10 and the gate insulating film 8, and the n⁺-type source regions 5 and the p⁺-type contact regions 6 are exposed by the contact hole (step S6). Next, the interlayer insulating film 10 is planarized by heat treatment (reflow) (step S7).

Next, a nickel (Ni) film is formed on the interlayer insulating film 10 so as to fill in the contact hole, and a silicide formation step is performed by sintering (step S8). Then, the source electrode 11 is formed as the front surface electrode and then patterned (step S9). Then, the drain electrode 13 is formed as the rear surface electrode on the rear surface of the silicon carbide substrate 20 (rear surface of the n⁺-type starting substrate 1) (step S10). Thereafter, by separating the semiconductor wafer into individual chips by dicing, the silicon carbide semiconductor device shown in FIG. 1 is completed. The mask used in ion implantation and etching may be a resist mask or an oxide film mask, for example.

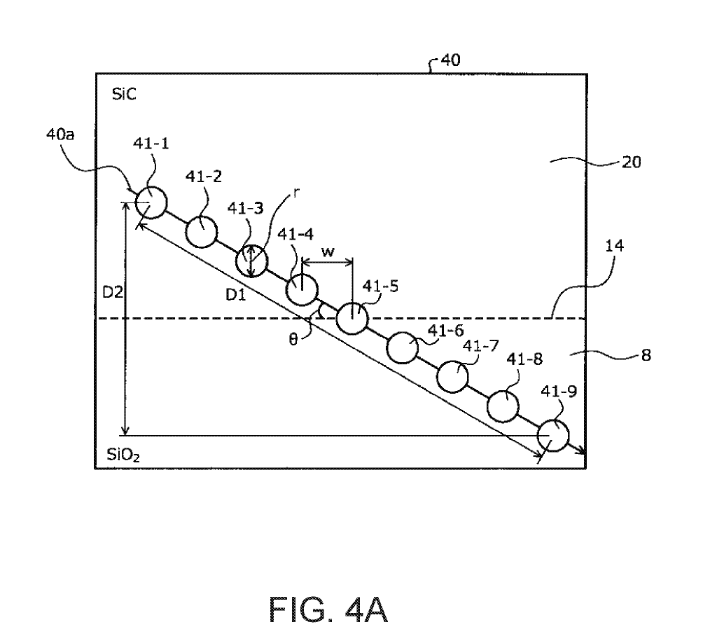

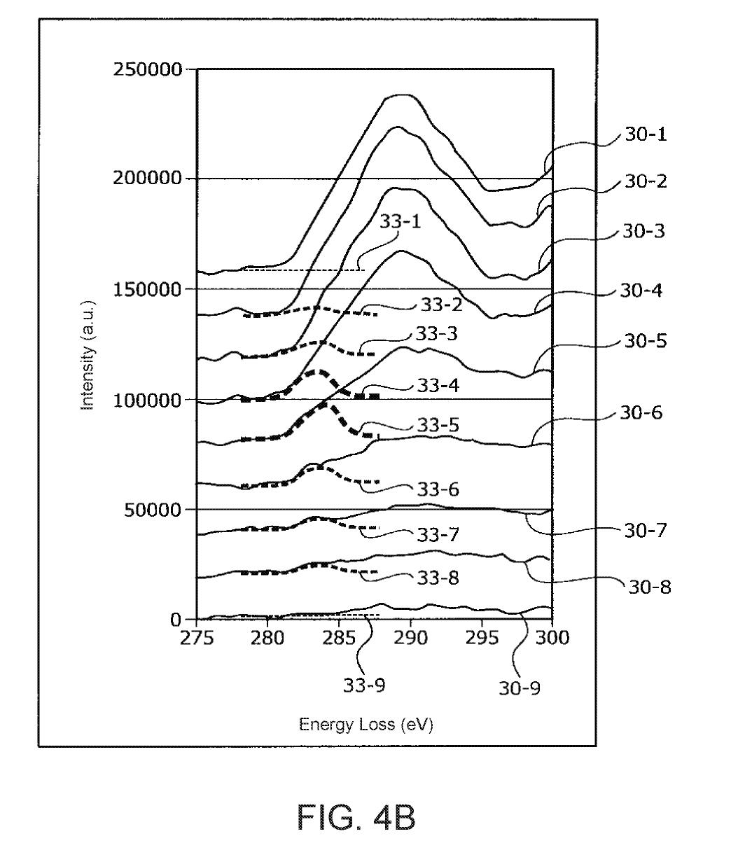

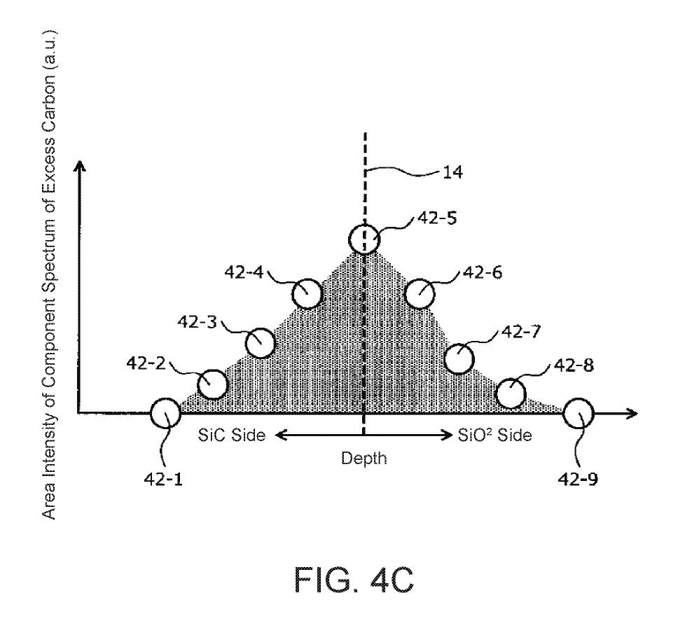

Next, the method for calculating the excess carbon ratio of the SiO₂/SiC interface 14 will be described. FIG. 3 is an energy loss intensity distribution chart showing an energy loss intensity distribution measured by EELS and spectra separated from the energy loss intensity distribution. The horizontal axis of FIG. 3 is the energy loss of the atoms (eV), and the vertical axis is the intensity (arbitrary unit (a.u.)) indicating the number of electrons that were detected to have respective energy loss values (this also applies to FIG. 4B). As shown in FIG. 3, an energy loss intensity distribution 30 measured by EELS is the sum of a spectrum 32 and a spectrum 34 due to the silicon carbide, and a spectrum 33 and a spectrum 35 due to the excess carbon. Although not indicated from the drawing, the spectrum of the carbon atoms due to the σ bond through the sp³ hybrid orbitals, the sp² hybrid orbitals, and the sp hybrid orbitals appears in a range exceeding the maximum energy loss value of the electrons due to the silicon carbide.

At each of measuring points in the vicinity of the SiO₂/SiC interface 14, the spectrum 32 and the spectrum 34 due to the silicon carbide, and the spectrum 33 and the spectrum 35 due to the excess carbon can be separated from the energy loss intensity distribution 31 that is obtained by curve-fitting the measured energy loss intensity distribution 30. Here, the spectrum 32 and the spectrum 34 due to silicon carbide can be obtained by curve-fitting the energy loss intensity distribution of the silicon carbide substrate region (measurement point 41-1 in FIG. 4A) that is located away from the interface 14. The spectrum 32 represents a spectrum due to carbon atoms having the sigma (σ) bond in the silicon carbide, and the spectrum 34 represents a spectrum due to ionization of the carbon atoms in the silicon carbide. Furthermore, the spectrum 33 represents a spectrum due to carbon atoms having the pi (π) bond in the excess carbon, and the spectrum 35 represents a spectrum due to the carbon atoms having the sigma (σ) bond in the excess carbon. In order to calculate the excess carbon ratio of the SiO₂/SiC interface 14, the energy loss intensity distribution 30 by EELS is acquired for a plurality of measurement points as described in detail below. Then, the spectrum 33 due to carbon atoms having the pi (n) bond in the excess carbon is separated from the energy loss intensity distribution 30 measured by EELS at each of a plurality of measurement points, and the separated spectrum 33 due to carbon atoms having the pi (π) bond in the excess carbon is integrated to calculate the area intensity of the spectrum 33 due to carbon atoms having the pi (π) bond in the excess carbon. At this time, the intensities of the spectra 32 and 34 of silicon carbide are adjusted appropriately in accordance with the curve fitting.

The method for calculating the area intensity of spectrum 33 due to carbon atoms having the pi (π) bond in the excess carbon will be described with reference to FIGS. 4A to 4C in more detail. FIG. 4A schematically shows measurement points 41-1 to 41-9 near the SiO₂/SiC interface 14 of the test piece 40 for EELS. FIG. 4A shows the test piece 40 as viewed from a surface perpendicular to the SiO₂/SiC interface 14 of the test piece 40. FIG. 4B is an energy loss intensity distribution chart showing respective energy loss intensity distributions 30-1 to 30-9 at the measurement points 41-1 to 41-9, respectively, in FIG. 4A and the spectrum due to excess carbon separated from the energy loss intensity distribution for each measuring point. FIG. 4C is a characteristic view showing an area intensity distribution of the spectrum due to excess carbon at each measurement point of FIG. 4A. The horizontal axis of FIG. 4C is the depth from the SiO₂/SiC interface 14 to the silicon carbide substrate 20 side (SiC side) and the gate insulating film 8 side (SiO₂ side), and the vertical axis is the area intensity (arbitrary unit (a.u.)) of the spectrum due to excess carbon.

The test piece 40 is prepared as follows. As shown in FIG. 4A, in the portion including the silicon carbide substrate 20 and the gate insulating film 8, a thin plate-shaped piece with a thickness of approximately 40 nm, for example, is cut out from the oxidized silicon carbide substrate 20 such that the surface perpendicular to the SiO₂/SiC interface 14 becomes the main surface of the thin plate-shaped piece. The resulting thin plate-shaped piece is the test piece 40. An electron beam is radiated in a transmission electron microscope to prescribed measurement points 41-1 to 41-9 from a direction perpendicular to the main surface of the test piece 40, and the energy loss of the electrons due to the interactions between the electrons and atoms in the test piece 40 is measured. As a result, the energy loss intensity distribution 30 (see FIG. 3) for each measurement point 41-1 to 41-9 of the test piece 40 is obtained. At this time, it is preferable that the measurement points 41-1 to 41-9 be in locations that do not include damage resulting from manufacturing of the test piece 40. The number of measurement points of the test piece 40 can be changed according to conditions of the test piece 40.

The measurement points 41-1 to 41-9 of the test piece 40 are set on a line 40a that is parallel to the main surface of the test piece 40 and that intersects the SiO₂/SiC interface 14. In FIG. 4A reference characters 41-1 to 41-9 are assigned to the respective measurement points of the test piece 40 in order from the deepest measurement point in the silicon carbide substrate 20 to the deepest measurement point in the gate insulating film 8. The line 40a on which the measurement points 41-1 to 41-9 of the test piece 40 are set may be 90 degrees to the SiO₂/SiC interface 14, but it is preferable that a prescribed inclination angle θ other than 90 degrees be used. The reason is that if the measurement points 41-1 to 41-9 are set on a line perpendicular to the SiO₂/SiC interface 14, this poses the risk of carbon contamination resulting from EELS measurement at other measurement points.

The inclination angle θ, in relation to the SiO₂/SiC interface 14, of the line 40a on which the measurement points 41-1 to 41-9 of the test piece 40 are set can be changed to a different angle, and may be approximately 30 degrees, for example. The spot diameter r of the electron beam radiated on the measurement points 41-1 to 41-9 of the test piece 40 and the gap w between adjacent measurement points 41-1 to 41-9 can be changed to various lengths, and may be approximately 0.2 nm and 0.4 nm, respectively, for example. However, it is preferable that the spot diameter r be less than the measurement gap w in order for the measurement locations not to overlap. The reference character D1 is a distance between the farthest apart measurement points 41-1 and 41-9 on the line 40a along the measurement points 41-1 to 41-9 (hereinafter referred to as “first analysis distance”). The reference character D2 is a distance in a direction perpendicular to the SiO₂/SiC interface 14 between the farthest apart measurement points 41-1 and 41-9 (hereinafter referred to as “second analysis distance”).

FIG. 4B shows the energy loss intensity distributions 30 and the respective spectra 33 due to carbon atoms having the pi (π) bond in the excess carbon separated from the energy loss intensity distributions 30, for the energy loss intensity distributions 30 measured at the measurement points 41-1 to 41-9 of the test piece 40.

As shown in FIG. 4B, the peak value of the measured energy loss intensity distribution 30 (as well as the curve-fitted energy loss intensity distribution 31) in the vicinity of the SiO₂/SiC interface 14 obtained for each measurement point 41-1 to 41-9 is the largest at the measurement point 41-1 that is deeper inside the silicon carbide substrate 20 from the SiO₂/SiC interface 14 and is the smallest at the measurement point 41-9 that is deeper inside the gate insulating film 8 from the SiO₂/SiC interface 14. The suffixes 1 to 9 of the energy loss intensity distributions 30 and the spectra 33 of FIG. 4B correspond, respectively, to the energy loss intensity distributions 30 and the spectra 33 of FIG. 3 detected at the measurement points 41-1 to 41-9 of FIG. 4A.

The energy loss intensity distribution 30 in the vicinity of the SiO₂/SiC interface 14 is the largest at the measurement point 41-1 because the silicon carbide substrate 20 is measured. On the other hand, the energy loss intensity distribution 30 indicating the bond energy intensity distribution in the vicinity of the SiO₂/SiC interface 14 is the smallest at the measurement point 41-9 because the gate insulating film 8 is measured.

As shown in FIG. 4C, the area intensity of the spectra 33-1 to 33-9 due to the excess carbon is the largest at the measurement point 41-5 on the SiO₂/SiC interface 14 of the test piece 40 in the example shown, and decreases as the distance from the SiO₂/SiC interface 14 increases, thus forming a mountain-shaped distribution. FIG. 4C indicates the plots of the measurement points 41-1 to 41-9 of the test piece 40 with reference characters 42-1 to 42-9, respectively. At the measurement points 41-1 and 41-9 of the test piece 40 that are farthest from the SiO₂/SiC interface 14, the area intensities of the spectrum due to excess carbon is zero. By integrating the area intensities 42-1 to 42-9 (FIG. 4C) of the spectra due to the excess carbon obtained at the measurement points 41-1 to 41-9 of the test piece 40, the total intensity of the spectra 33 due to carbon atoms having the pi (π) bond in the excess carbon (shaded portion in FIG. 4C) is calculated. The total intensity of the spectra 33 due to carbon atoms having the pi (π) bond in the excess carbon represents the total amount of the excess carbon at the SiO₂/SiC interface 14.

The energy loss intensity distribution at the measurement point 41-1 that is the farthest from the SiO₂/SiC interface 14 can solely be attributed to the silicon carbide substrate. Thus, the spectrum 32 due to carbon atoms having the sigma (σ) bond in the silicon carbide was obtained by fitting the energy loss intensity distribution of the measurement point 41-1, and the area intensity thereof was deemed to represent the amount of the carbon of the silicon carbide in the silicon carbide substrate. The ratio of the total intensity of the spectra 33 due to carbon atoms having the pi (π) bond in the excess carbon (amount obtained by adding 42-1 to 42-9) relative to the area intensity is defined as the excess carbon ratio at the SiO₂/SiC interface 14 in this disclosure.

### Working Example

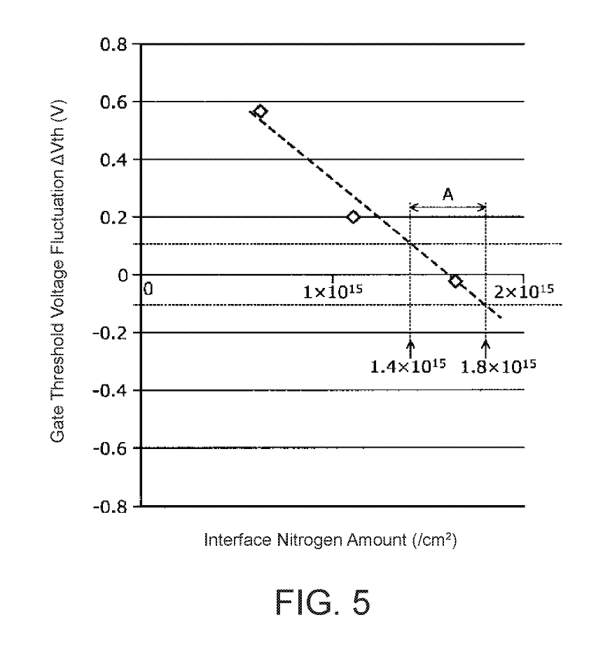

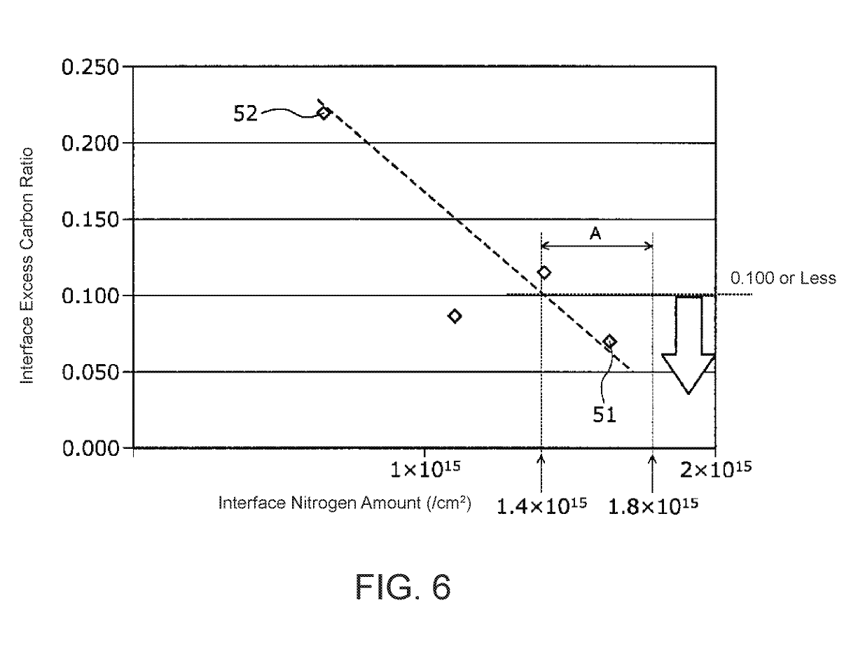

The excess carbon ratio of the SiO₂/SiC interface 14 was measured using a working example of the present invention. FIG. 5 is a characteristic figure showing the relationship between the amount of nitrogen at the SiO₂/SiC interface (interface nitrogen amount) and the gate threshold voltage shift ΔVth. FIG. 6 is a characteristic figure showing the relationship between the amount of nitrogen at the SiO₂/SiC interface (interface nitrogen amount) and the excess carbon ratio at the SiO₂/SiC interface (interface excess carbon ratio). For each of a plurality of samples including the silicon carbide semiconductor device structure according to the above-mentioned embodiment (see FIG. 1), an AC (alternating current) voltage was applied for a prescribed time to the gate electrode 9 at room temperature (approximately 25° C., for example) (hereinafter referred to as AC application test), and then the gate threshold voltage shift ΔVth was calculated. Results thereof are shown in FIG. 5. Each sample differs in terms of the amount of nitrogen at the SiO₂/SiC interface 14. The gate threshold voltage shift ΔVth is the difference between the gate threshold voltage Vth prior to the AC application test and the gate threshold voltage Vth after the AC application test.

The structure of each sample was a planar gate structure horizontal MOSFET. For the silicon carbide substrate 20, an n-type 4H—SiC (four-layer periodic hexagonal crystal of silicon carbide) substrate where the (0001) surface having an off angle of approximately 4 degrees in the <11-20> direction is the front surface was used. After the front surface of the silicon carbide substrate 20 was cleaned with hydrogen fluoride, the silicon carbide substrate 20 was subjected to thermal oxidation in an oxygen atmosphere with a pressure of one atmosphere at a temperature of 1200° C. for 150 minutes (first heat treatment), and then subjected to thermal oxidation in an oxynitride atmosphere including 10% nitrous oxide at atmospheric pressure for 120 minutes (second heat treatment), to form the gate insulating film 8. The total thickness of the gate insulating film 8 formed by the two rounds of heat treatment is 50 nm. The temperature of the second round of heat treatment was set to 1300° C. in the working examples, and set to 1150° C. in a comparison example to be described later. The carrier gas for the second round of heat treatment was N₂ gas.

During the AC application test for each sample, the AC voltage applied to the gate electrode 9 (gate signal) was a pulse signal of −5 V in the low state (minimum value) and +10 V in the high state (maximum value). The frequency of the pulse signal was set to 20 kHz with a duty cycle of 50% (pulse width of high state=pulse width of low state). The amount of time that the AC voltage was applied to the gate electrode 9 was set to 100 hours (h). During the AC application test, no voltage was applied between the source and drain of each sample. Here, the excess carbon ratio of the SiO₂/SiC interface 14 was examined with respect to the case of reducing the tolerance of the gate threshold voltage shift ΔVth to ±0.1 V or less.

From the results shown in FIG. 5, it was realized that when the amount of nitrogen at the SiO₂/SiC interface 14 is in a range A of 1.4×10¹⁵/cm² to 1.8×10¹⁵/cm², inclusive, the gate threshold voltage shift ΔVth can be suppressed to ±0.1V or less. The amount of nitrogen at the SiO₂/SiC interface 14 was measured by secondary ion mass spectrometry (SIMS). In the present working example, nitrogen was not used in the first round of thermal oxidation, but was introduced during the second round of thermal oxidation in an oxynitride atmosphere, and thus, nitrogen is mostly concentrated near the SiO₂/SiC interface 14. Thus, a value calculated by integrating the nitrogen distribution obtained from a structure straddling the gate insulating film 8 to the silicon carbide substrate 20 was used as the amount of nitrogen at the SiO₂/SiC interface 14. For each sample, the results of calculating the excess carbon ratio at the SiO₂/SiC interface 14 (interface excess carbon ratio) by EELS as described above are shown in FIG. 6.

Measurement of the bond energy intensity by EELS was performed by setting the spot diameter r of the electron beam with which the sample was radiated in the transmission electron microscope to 0.2 nm, and the electron beam was radiated such that measurement points were located on the line 40a with an angle θ of 30 degrees to the SiO₂/SiC interface 14 (see FIG. 4A). The electron beam radiation time at each measurement point was set to 3 seconds. The bond energy intensity at 42 measurement points was measured with the first analysis distance D1 between the farthest apart measurement points being set to 17 nm, the second analysis distance D2 being set to 8.5 nm, and the gap w between adjacent measurement points being set to 0.4 nm.

From the results shown in FIG. 6, it was confirmed that as the amount of nitrogen at the SiO₂/SiC interface 14 was increased, the excess carbon ratio at the SiO₂/SiC interface 14 decreased in proportion to the increase in the amount of nitrogen at the SiO₂/SiC interface 14. Also, in order to suppress the gate threshold voltage shift ΔVth to ±0.1 V or less, it was confirmed that the amount of nitrogen at the SiO₂/SiC interface 14 needs to be in the above-mentioned range A, and the excess carbon ratio at the SiO₂/SiC interface 14 must meet at least a condition of being 0.1 or less (indicated with the white arrow).

In other words, in FIG. 6, samples where the amount of nitrogen at the SiO₂/SiC interface 14 is within the range A are samples that conform to the conditions of the present invention (hereinafter referred to as working examples). In the sample 51 of a working example, for example, the amount of nitrogen at the SiO₂/SiC interface 14 was 1.6×10¹⁵/cm², and the excess carbon ratio of the SiO₂/SiC interface 14 based on the measurement results by EELS was 0.07. Also, the gate threshold voltage shift ΔVth of the sample 51 of the working example was 0.03 V, and the interface state density at the SiO₂/SiC interface 14 was 1×10¹²/cm²/eV. The interface state density was obtained using the Hi-Lo method by analyzing the C-V curve data measured at a high frequency of 1 MHz and a low frequency of 200 Hz.

On the other hand, among the samples shown in FIG. 6, samples where the amount of nitrogen at the SiO₂/SiC interface 14 is outside of the range A are comparison examples. In the sample 52 of a comparison example, for example, the amount of nitrogen at the SiO₂/SiC interface 14 was 7×10¹⁴/cm², and the excess carbon ratio of the SiO₂/SiC interface 14 based on the measurement results by EELS was 0.22. Also, the gate threshold voltage shift ΔVth of the sample 52 of the comparison example was 0.6 V, and the interface state density at the SiO₂/SiC interface 14 was 5×10¹²/cm²/eV.

In the working examples, it was realized that the amount of nitrogen at the SiO₂/SiC interface 14 can be set to within the above-mentioned range, and the excess carbon ratio at the SiO₂/SiC interface 14 can be set to 0.1 or less. The working examples and comparison examples differ in terms of the thermal oxidation temperature of the oxynitride atmosphere for forming the gate insulating film 8 as described above. Thus, it can be seen that by adjusting the thermal oxidation temperature in the oxynitride atmosphere, it is possible to adjust the amount of nitrogen at the SiO₂/SiC interface 14. Here, the thermal oxidation temperature of the oxynitride atmosphere in the working examples was set to 1300° C., but similar effects can be attained as long as thermal oxidation in the oxynitride atmosphere is performed at a temperature of 1200° C. to 1500° C., inclusive.

As described above, in the above-described embodiments, by setting the amount of nitrogen at the SiO₂/SiC interface to within the above range, it is possible to reduce the amount of excess carbon at the SiO₂/SiC interface. As a result, the interface state (electron trap) density at the SiO₂/SiC interface is reduced, and thus, it is possible to mitigate channel mobility reduction and gate threshold voltage fluctuation. Also, according to the above-described embodiments, by forming the gate insulating film by thermal oxidation in an oxynitride atmosphere (process of step S4), it is possible to improve and stabilize MOS gate characteristics.

The present invention described above is not limited to the above embodiment, and various modifications can be made without departing from the spirit of the present invention. For example, in the above embodiment, the excess carbon ratio at the SiO₂/SiC interface was calculated for a case in which the tolerance for the shift ΔVth in the gate threshold voltage Vth was ±0.1 V or less, but the tolerance for the shift ΔVth in the gate threshold voltage Vth can be set to various values depending on the specifications of the product. Also, the number and arrangement of measurement points for EELS performed in order to calculate the excess carbon ratio at the SiO₂/SiC interface, and the radiation conditions for the electron beam can be modified according to the structure of the silicon carbide semiconductor device. Additionally, by performing a heat treatment step in an oxynitride atmosphere after forming a deposition film as the gate insulating film, it is possible to apply the present invention to a case in which the surface of the silicon carbide substrate in contact with the deposited film is subjected to thermal oxidation.

Also, the present invention can be applied to silicon carbide semiconductor devices with various structures provided with a MOS gate where a thermally oxidized film provided on the main surface of the silicon carbide substrate is the gate insulating film. For example, the present invention can be applied to a MOS-type silicon carbide semiconductor device such as a MOSFET or an IGBT (insulated gate bipolar transistor), and the structure may be any one of a vertical type, horizontal type, planar gate structure, and trench gate structure. Also, the present invention exhibits similar effects even when a p-type silicon carbide substrate is used instead of an n-type silicon carbide substrate.

As described above, a silicon carbide semiconductor device and a method of manufacturing a silicon carbide semiconductor device according to the present invention are effective for MOS-type silicon carbide semiconductor devices.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A silicon carbide semiconductor device, comprising:
a semiconductor substrate made of silicon carbide;
a gate insulating film in contact with the semiconductor substrate on one main surface of the semiconductor substrate; and
a gate electrode that is provided along the gate insulating film, and that opposes the semiconductor substrate with the gate insulating film sandwiched therebetween,
wherein the gate insulating film is a thermally oxidized film,
wherein nitrogen and excess carbon made of carbon atoms having the pi (n) bonds are present at an interface between the gate insulating film and the semiconductor substrate,
wherein a ratio of an amount of the excess carbon at the interface between the gate insulating film and the semiconductor substrate, to an amount of carbon in a bulk of the semiconductor substrate is 0.1 or less,
wherein the amount of the excess carbon at the interface between the gate insulating film and the semiconductor substrate is determined by an integral of area intensities of energy loss intensity distributions due to carbon atoms having the pi (π) bonds in the excess carbon obtained by Electron Energy Loss Spectroscopy, and
wherein the amount of the carbon in the bulk of the semiconductor substrate is determined by an area intensity of an energy loss intensity distribution due to carbon atoms having the sigma (σ) bonds in the silicon carbide of the bulk of the semiconductor substrate obtained by the Electron Energy Loss Spectroscopy.

2. The silicon carbide semiconductor device according to claim 1,
wherein an amount of the nitrogen at the interface between the gate insulating film and the semiconductor substrate is 1.4×10¹⁵/cm² to 1.8×10¹⁵/cm², inclusive.

3. A silicon carbide semiconductor device, comprising:
a semiconductor substrate made of silicon carbide;
a gate insulating film in contact with the semiconductor substrate on one main surface of the semiconductor substrate; and
a gate electrode that is provided along the gate insulating film, and that opposes the semiconductor substrate with the gate insulating film sandwiched therebetween,
wherein the gate insulating film is a thermally oxidized film,
wherein nitrogen and excess carbon made of carbon atoms having the pi (n) bonds are present at an interface between the gate insulating film and the semiconductor substrate, and
wherein an amount of the nitrogen at the interface between the gate insulating film and the semiconductor substrate is 1.4×10¹⁵/cm² to 1.8×10¹⁵/cm², inclusive.

4. A method of manufacturing a silicon carbide semiconductor device, comprising:
preparing a semiconductor substrate made of silicon carbide;
forming a gate insulating film on the semiconductor substrate, including thermally oxidizing a surface of the semiconductor substrate; and
forming a gate electrode on the gate insulating film,
wherein the gate insulating film is formed such that an amount of nitrogen accumulated at an interface between the gate insulating film and the semiconductor substrate is 1.4×10¹⁵/cm² to 1.8×10¹⁵/cm², inclusive.

5. The method of manufacturing a silicon carbide semiconductor device according to claim 4, wherein the gate insulating film is formed such that a ratio of an amount of excess carbon made of carbon atoms having the pi (π) bonds accumulated at the interface between the gate insulating film and the semiconductor substrate, to an amount of carbon in a bulk of the semiconductor substrate is set to 0.1 or less,
wherein the amount of the excess carbon at the interface between the gate insulating film and the semiconductor substrate is determined by an integral of area intensities of energy loss intensity distributions due to carbon atoms having the pi (π) bonds in the excess carbon obtained by Electron Energy Loss Spectroscopy, and
wherein the amount of the carbon in the bulk of the semiconductor substrate is determined by an area intensity of an energy loss intensity distribution due to carbon atoms having the sigma (σ) bonds in the silicon carbide of the bulk of the semiconductor substrate obtained by the Electron Energy Loss Spectroscopy.

6. The method of manufacturing a silicon carbide semiconductor device according to claim 4,
wherein the formation of the gate insulating film includes thermally oxidizing the semiconductor substrate in an oxynitride atmosphere including nitrogen monoxide or nitrous oxide.

7. The method of manufacturing a silicon carbide semiconductor device according to claim 5,
wherein the formation of the gate insulating film includes thermally oxidizing the semiconductor substrate in an oxynitride atmosphere including nitrogen monoxide or nitrous oxide.

8. The method of manufacturing a silicon carbide semiconductor device according to claim 4,
wherein the formation of the gate insulating film includes performing dry oxidation of the semiconductor substrate using dry oxygen as an oxidant, and subsequently thermally oxidizing the semiconductor substrate in an oxynitride atmosphere including nitrogen monoxide or nitrous oxide.

9. The method of manufacturing a silicon carbide semiconductor device according to claim 5,
wherein the formation of the gate insulating film includes performing dry oxidation of the semiconductor substrate using dry oxygen as an oxidant, and subsequently thermally oxidizing the semiconductor substrate in an oxynitride atmosphere including nitrogen monoxide or nitrous oxide.

10. The method of manufacturing a silicon carbide semiconductor device according to claim 4,
wherein the formation of the gate insulating film includes performing wet oxidation of the semiconductor substrate using water vapor as an oxidant, and subsequently thermally oxidizing the semiconductor substrate in an oxynitride atmosphere including nitrogen monoxide or nitrous oxide.

11. The method of manufacturing a silicon carbide semiconductor device according to claim 5,
wherein the formation of the gate insulating film includes performing wet oxidation of the semiconductor substrate using water vapor as an oxidant, and subsequently thermally oxidizing the semiconductor substrate in an oxynitride atmosphere including nitrogen monoxide or nitrous oxide.

12. The method of manufacturing a silicon carbide semiconductor device according to claim 4,
wherein the thermal oxidation of the semiconductor substrate is performed at a temperature of 1200° C. to 1500° C., inclusive.

13. The method of manufacturing a silicon carbide semiconductor device according to claim 5,
wherein the thermal oxidation of the semiconductor substrate is performed at a temperature of 1200° C. to 1500° C., inclusive.

14. The method of manufacturing a silicon carbide semiconductor device according to claim 6,
wherein the thermal oxidation of the semiconductor substrate in the oxynitride atmosphere including nitrogen monoxide or nitrous oxide is performed at a temperature of 1200° C. to 1500° C., inclusive.

15. The method of manufacturing a silicon carbide semiconductor device according to claim 8,
wherein the thermal oxidation of the semiconductor substrate in the oxynitride atmosphere including nitrogen monoxide or nitrous oxide is performed at a temperature of 1200° C. to 1500° C., inclusive.

16. The method of manufacturing a silicon carbide semiconductor device according to claim 10,
wherein the thermal oxidation of the semiconductor substrate in the oxynitride atmosphere including nitrogen monoxide or nitrous oxide is performed at a temperature of 1200° C. to 1500° C., inclusive.
